(19) United States
(12) Patent Application Publication
(10) Pub. No.: US 2026/0320123 A1
(43) Pub. Date: Oct. 15, 2026

(54) Method and device for rapidly constructing field signature method databases

(71) Applicant: China University of Petroleum (East China), Qingdao City (CN)

(72) Inventors: Yan LI, Qingdao City (CN); Tao JIANG, Qingdao City (CN); Wanpeng YAO, Qingdao City (CN); Yujia ZHAI, Qingdao City (CN); Jingyi ZHAO, Qingdao City (CN)

(73) Assignee: China University of Petroleum (East China), Qingdao City (CN)

(21) Appl. No.: 19/578,845

(22) Filed: Mar. 25, 2026

(30) Foreign Application Priority Data
Mar. 29, 2025 (CN) 2025103854717

(51) Int. Cl. G06F 16/901; G06F 30/20

(52) U.S. Cl. CPC G06F 16/901; G06F 30/20

(57) ABSTRACT

A method and a device for rapidly constructing field signature method databases, and the method includes: S1—simulation requirements analysis, including calculating electric field distribution information of monitored components containing pitting corrosion; S2—simulation parameter settings, establishing simulation calculation models of the monitored components; S3—simulation calculation: based on set simulation parameters, calculating electric field distribution information of models with and without pitting corrosion under all single parameters; S4—extracting potential information from simulation models and constructing a potential matrix: based on preset electrode matrix parameters, constructing an electric field data extraction coordinate matrix and extracting potential information corresponding to each coordinate; S5—data post-processing: based on the potential matrix, constructing an initial potential difference matrix and a collected potential difference matrix respectively, and then calculating an FC value matrix; S6—data storage: inserting the aforementioned parameters and matrices into an existing pitting corrosion database.

### CROSS-REFERENCE

This application claims the benefit of priority from China Patent Application No. CN 2025103854717 filed on Mar. 29 2025, the contents of which are hereby incorporated by reference in their entirety.

### TECHNICAL FIELD

The present invention belongs to the field of corrosion monitoring technology, specifically relating to a method and a device for rapidly constructing field signature method databases.

### BACKGROUND TECHNOLOGY

In the oil and gas industry, property losses due to pipe corrosion failure can account for 3% to 5% of the GDP, making corrosion monitoring of oil and gas pipes extremely important. FSM (Field Signature Method) technology, with its significant advantages, has been increasingly widely used in corrosion monitoring in recent years; however, the accuracy of current field signature monitoring databases and data inversion remains relatively low.

With the development of computer technology and the maturity of numerical simulation techniques, more and more practical engineering problems are relying on model simulation to find specific implementation methods for practical engineering applications from the simulation results. In numerical simulation technology, one application method is to obtain a large amount of simulation data and establish a mathematical model, using the established mathematical model to solve practical engineering problems. However, establishing model databases are often not only inefficient but also cumbersome in terms of data retrieval.

### SUMMARY OF THE INVENTION

The present invention aims to at least partially solve one of the technical problems in the aforementioned related technologies.

Therefore, the object of the present invention is to provide a method and a device for rapidly constructing field signature method databases, which can efficiently and quickly construct field signature method databases.

To solve the above technical problems, the present invention is implemented as follows:

Embodiments of the present invention provide a method for rapidly constructing field signature method databases, including following steps of:
S1—performing simulation requirements analysis, which includes calculating electric field distribution information of monitored components with pitting corrosion;
S2—setting simulation parameters and establishing simulation calculation models of the monitored components;
S3—performing simulation calculations: according to set simulation parameters, calculating electric field distribution information of models with pitting corrosion and models without pitting corrosion under all single parameters;
S4—extracting potential information from simulation models and constructing a potential matrix: according to preset electrode matrix parameters, constructing an electric field data extraction coordinate matrix and extracting potential information corresponding to coordinates;
S5—data post-processing: according to the potential matrix, constructing an initial potential difference matrix and a collected potential difference matrix respectively, and then calculating an FC value matrix, and
S6—data storage: inserting the simulation parameters, potential difference matrices, and FC value matrix as mentioned above into an existing pitting corrosion database.

Moreover, the method for rapidly constructing field signature method databases according to the present further includes following additional technical features:

In some embodiments, the method further includes: traverse the steps S4-S6 to ensure that data for all parameters is stored in the pitting corrosion database.

In some embodiments, the method further includes: using the simulation parameters and querying calculation results under the simulation parameters in the pitting corrosion database.

In some embodiments, the step S1 includes confirming to-be-monitored object information, simulation calculation objectives, requirements, and corrosion defect information included for filed signature monitoring, and calculating electric field distribution information of monitored components with pitting corrosion based on the to-be-monitored object information, the simulation calculation objectives, the requirements, and the corrosion defect information included.

In some embodiments, the step S2 includes following specific steps of:
S21—system construction: determining a programming language, multiphysics simulation software, and a database;
S22—setting model parameters of the monitored components, which include dimensions and material of the monitored components;
S23—setting pitting corrosion parameters: setting morphology parameters of the monitored components when pitting corrosion occurs, including pitting coordinate information and morphology parameter information; and
S24—setting physical field parameters: adding physical field parameters to the simulation models, applying direct current to both ends of the monitored components, and establishing simulation calculation models of the monitored components.

In some embodiments, the morphology parameter information in the step S23 includes pitting radius and pitting depth.

In some embodiments, the step S3 includes:
calculation of models without pitting corrosion: selecting a single parameter from the simulation parameters of the monitored components as a parameter used for calculation, and calculating electric field distribution information of monitored component models without pitting corrosion under the single parameter; and
calculation of models with pitting corrosion: using the parameter in the calculation of models without pitting corrosion, and calculating electric field distribution information of monitored component models with pitting corrosion under the parameter.

In some embodiments, the step S4 includes following specific steps of:
S41—constructing an electrode matrix: setting electrode matrix parameters of monitored component models, obtaining electrode coordinate information under different electrode matrix arrangements, and forming the electrode matrix; and
S42—constructing a potential matrix: according to the electrode coordinate information obtained, extracting potential information of sampling points contained in the electrode matrix, and obtaining the potential matrix.

In some embodiments, the step S5 includes:
according to the potential matrix, calculating potential differences between any two adjacent electrodes under both non-corroded and pitted corrosion conditions of the monitored components, obtaining an initial potential difference matrix and a collected potential difference matrix containing all electrode sites; and
according to the collected potential difference matrix and the initial potential difference matrix, calculating an FC value matrix, wherein
an FC value is a ratio of voltage values under the non-corroded and pitted corrosion conditions.

The method for calculating a single FC value is a ratio of a single potential difference measured by a pair of electrodes at the time when pitting corrosion occurs (time t) to the time when pitting corrosion does not occur (time t₀).

Embodiments of the present invention provides a device for rapidly constructing field signature method databases, including a memory, a processor, and a computer program stored in the memory and executable on the processor, wherein the processor executes the computer program to implement the steps of the method for rapidly constructing field signature method databases according to any one of the method for rapidly constructing field signature method databases as mentioned above.

Compared with existing technologies, the present invention has at least following beneficial effects:

In the embodiments of the present invention, the method for rapidly constructing field signature method databases, through program-controlled model parameters calling commercial simulation software and connecting to a database, can realize the combined solution of different parameter ranges of a single model, as well as the combined solution of different parameters of different models, and realize the calculation and storage of simulation results. The solution and application are very convenient and fast, and it can be widely adapted to simulation situations where model calculation parameters vary and multiple models are used in conjunction, thereby realizing the establishment of a database of calculation results for multiple model parameters of FSM technology.

The device for rapidly constructing field signature method databases of the present invention can realize the aforementioned method for rapid construction of rapidly constructing field signature method databases, and therefore possesses at least all the features and advantages of the aforementioned method, which will not be elaborated further here. Additional aspects and advantages of the present invention will be set forth in part in the description which follows, and in part will be obvious from the description, or may be learned by practice of the present invention.

### BRIEF DESCRIPTION OF THE DRAWINGS

FIG. 1 is a flowchart of a method for rapidly constructing filed signature method databases according to an embodiment of the present invention.

FIG. 2 is a schematic diagram of a model parameter setting interface for a method for rapidly constructing filed signature method databases according to an embodiment of the present invention.

FIG. 3 is a schematic diagram of an electrode matrix setting interface for a method for rapidly constructing filed signature method databases according to an embodiment of the present invention.

FIG. 4 is a schematic diagram of a data query interface for a method for rapidly constructing filed signature method databases according to an embodiment of the present invention.

### SPECIFIC EMBODIMENTS

The technical solutions of the embodiments of the present invention will be clearly and completely described below with reference to the accompanying drawings. Obviously, the described embodiments are only some, not all, of the embodiments of the present invention. All other embodiments obtained by those skilled in the art based on the embodiments of the present invention without creative effort are within the scope of protection of the present invention.

The embodiments of the present invention will be described in detail below with reference to the accompanying drawings through specific examples and application scenarios thereof.

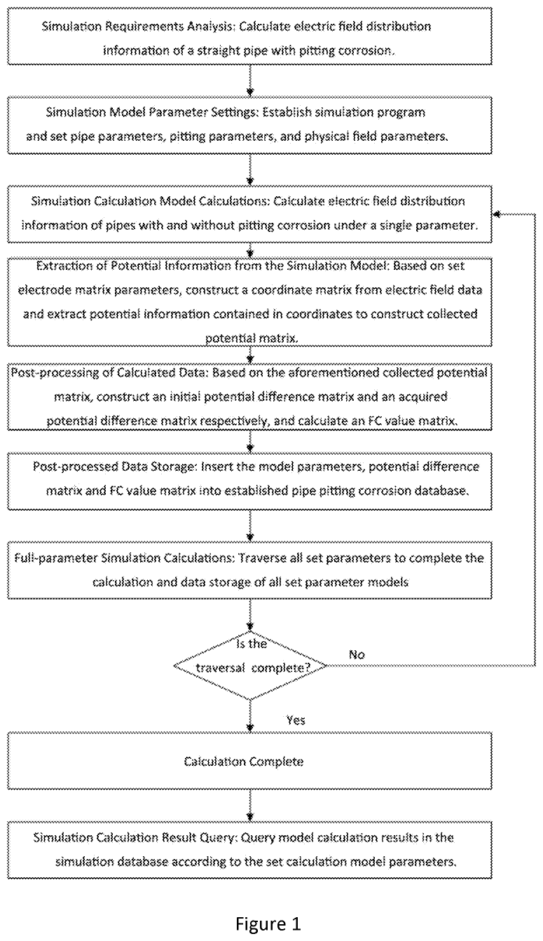

Please refer to FIG. 1, in some embodiments of the present invention, a method for rapidly constructing filed signature method databases is provided. The method targets the monitored object as an array electrode corrosion component, that is, the signal acquisition electrode has several electrodes arranged in an array and fixed on the surface of the component to be corroded, such as the surface of a straight pipe with pitting corrosion.

The method includes following steps of:

Step 1: Simulation Calculation Requirements Analysis: Calculate electric field distribution information of monitored components containing pitting corrosion.

This step requires clarifying the to-be-monitored object information for FSM technology, confirming the simulation calculation objectives, requirements, and included corrosion defect information. The to-be-monitored object information includes the pipe's geometric parameters (diameter, wall thickness, material), anti-corrosion layer parameters (thickness, resistivity), and soil environmental parameters (conductivity, water content), etc. Simulation calculation objectives and requirements include simulation accuracy, boundary conditions (such as applied current), and calculation methods (such as the finite element method), etc. Corrosion defect information includes the geometric characteristics of pitting corrosion (size, depth, location) and the electrical properties of corrosion products (resistivity), etc. Based on this determined information, the electric field distribution information of the monitored component containing pitting corrosion (such as straight pipes) is calculated.

Simulated electric field signature non-destructive testing technology is used for the inspection of straight pipes with pitting corrosion, including the detection of the electric field on the outer surface of pipes that are not corroded and that have pitted corrosion. The simulation principle is to apply a constant current to both ends of the pipes, deploy electrodes on the outer surfaces of the pipes, and measure the voltage values between two adjacent electrodes. In other words, the voltage measurement on the outer surfaces reflects the distribution of defects inside the pipes.

Step 2: Simulation Model Parameter Settings: Establish the simulation program and set model parameters (such as pipe parameters), pitting corrosion parameters, and physics parameters.

Simulation model can be pipes, flat plates, or elbows, etc. Model defects include uniform corrosion, pitting corrosion, and cracks. Simulation model parameters include geometric parameters, mesh parameters, material parameters, physics parameters, and coordinate parameters. Simulation model parameters are a collection of different calculation parameters; they can be a uniform distribution of a single parameter or a complete combination of multiple parameters with different values. The step 2 includes following steps:

Step 2.1: System Construction: Select a programming language (MATLAB, Java, etc.), multiphysics simulation software (COMSOL, etc.), and database (MySQL, etc.).

Step 2.2: Pipe Parameter Settings: Set parameters of the pipe simulation models, including pipe length, outer diameter, wall thickness, and material.

Step 2.3: Pitting Corrosion Parameter Settings: Set the morphological parameters of the pipe when pitting corrosion occurs, including pitting coordinate information and morphological parameter information, where the morphological parameter information includes pitting radius and pitting depth.

Step 2.4: Physics Field Parameter Settings: Add physics field parameters to the simulation model, add DC current to both ends of the pipes, and establish the pipe simulation calculation models.

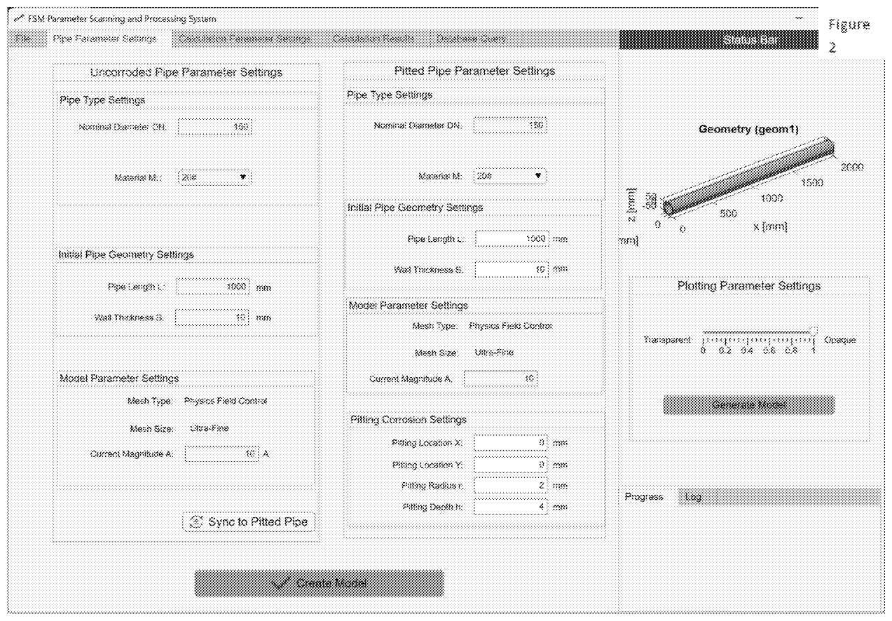

FIG. 2 shows a simulation calculation example of the present invention.

Step 3: Simulation Calculation Model: Calculate the electric field distribution information of pipes without pitting corrosion and with pitting corrosion under a single parameter.

For the set model parameters, calculate according to the set parameters to obtain the electric field distribution information of the simulation model. Step 3 includes the following steps:

Step 3.1: Calculation of the pipe models without pitting corrosion: Select a single parameter from the pipe setting parameter array as the pipe setting parameter and calculate the electric field distribution information of the models under the single pipe parameter.

Step 3.2: Calculation of the pipe models with pitting corrosion: Calculate the pipe models with pitting corrosion under the same setting parameters as in Step 3.1.

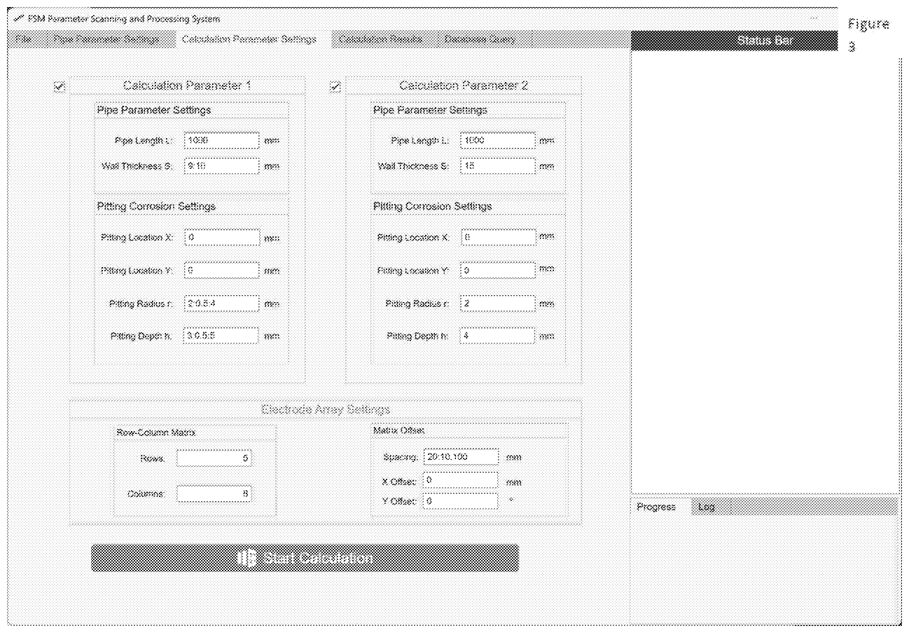

Step 4: Simulation Model Potential Information Extraction: Based on the set electrode matrix parameters, an electric field data extraction coordinate matrix is constructed. The potential information contained in the coordinates is then extracted to construct a collected potential matrix. Specifically, the voltage values of the outer surface electrode array of the pipe models are extracted. An extraction example of the present invention is shown in FIG. 3.

In this step, the data extraction coordinate information is set. The coordinate information is a two-dimensional matrix. The coordinate information can be a single coordinate or a combination of multiple coordinates, including the coordinate information of each collected electrode under different electrode layout schemes. The potential values of the set coordinate information points are then extracted. Step 4 includes the following steps:

Step 4.1: Construct the electrode coordinate matrix: Set the electrode matrix parameters on the outer surfaces of the pipe models, including the array dimension and array spacing. Based on the set pipe parameters and electrode matrix information, calculate the collected electrode coordinate information under different electrode matrix arrangements. The electrode matrix parameters can be a combination of multiple parameters to realize the potential information collection under different electrode arrangement schemes.

Taking the i-th row and j-th column electrode matrix as an example, the constructed collected electrode coordinate parameter matrix is as follows:

$$CM = [ \begin{matrix}[ {x}_{1} , {y}_{1} , {z}_{1} ] & ⋯ & [ {x}_{j} , {y}_{1} , {z}_{1} ] \\ ⋮ & ⋱ & ⋮ \\ [ {x}_{1} , {y}_{i} , {z}_{i} ] & ⋯ & [ {x}_{j} , {y}_{i} , {z}_{i} ]\end{matrix} ] ,$$

Where x, y, and z represent the coordinate information of the collected electrode.

Step 4.2: Construct the collected potential matrix: Based on the extracted coordinate information, extract the potential information of the collected electrodes contained in the electrode matrix, and construct the collected potential matrix:

$$PM = [ \begin{matrix}{p}_{11} & ⋯ & {p}_{1 j} \\ ⋮ & ⋱ & ⋮ \\ {p}_{i 1} & ⋯ & {p}_{ij}\end{matrix} ]$$

Where pᵢⱼ is the potential value in the i-th row and j-th column.

Step 5: Post-processing of data: Based on the above-mentioned collected potential matrix, construct the initial potential difference matrix and the acquired potential difference matrix respectively, and calculate the FC value matrix.

Based on the potential information contained in the extracted coordinate information, the potential difference between adjacent coordinates is calculated, and a collected potential difference matrix is constructed. Further, based on the collected potential difference matrix and the initial potential difference matrix, the collected FC value matrix is calculated. The FC value is the ratio of the voltage value acquired by the electrode matrix on the outer surface of the uncorroded pipe to the voltage value collected by the electrode array on the outer surface of the pitted pipe. Step 5 includes the following steps:

Step 5.1: Construct the collected potential difference matrix: Based on the above collected potential matrix, calculate the potential difference between adjacent coordinates and construct the potential difference matrix:

$$VM = [ \begin{matrix}{p}_{11} - {p}_{12} & ⋯ & {p}_{1 ( j - 1 )} - {p}_{1 j} \\ ⋮ & ⋱ & ⋮ \\ {p}_{i 1} - {p}_{i 2} & ⋯ & {p}_{i ( j - 1 )} - {p}_{ij}\end{matrix} ] = [ \begin{matrix}{v}_{11} & ⋯ & {v}_{1 n} \\ ⋮ & ⋱ & ⋮ \\ {v}_{m 1} & ⋯ & {v}_{mn}\end{matrix} ] ,$$

where vₘₙ is the potential difference value in the m-th row and n-th column of the potential difference matrix.

Step 5.2: Construct the initial potential difference matrix: Similar to the steps above, construct the potential matrix of the straight pipe without pitting corrosion, and then construct the initial potential difference matrix:

$$V 0 M = [ \begin{matrix}v {0}_{11} & ⋯ & v {0}_{1 n} \\ ⋮ & ⋱ & ⋮ \\ v {0}_{m 1} & ⋯ & v {0}_{mn}\end{matrix} ] ,$$

where v0ₘₙ is the potential difference value in the m-th row and n-th column of the initial potential difference matrix.

Step 5.3: Construct the FC value calculation matrix: Based on the collected potential difference matrix and the initial potential difference matrix, calculate the collected FC value matrix:

$$FCM = ( [ \begin{matrix}\frac{{v}_{11}}{v {0}_{11}} & ⋯ & \frac{{v}_{1 n}}{v {0}_{1 n}} \\ ⋮ & ⋱ & ⋮ \\ \frac{{v}_{m 1}}{v {0}_{m 1}} & ⋯ & \frac{{v}_{mn}}{v {0}_{mn}}\end{matrix} ] - 1 ) * 1000 = [ \begin{matrix}{fc}_{11} & ⋯ & {fc}_{1 n} \\ ⋮ & ⋱ & ⋮ \\ {fc}_{m 1} & ⋯ & {fc}_{mn}\end{matrix} ]$$

where fcₘₙ is the FC value in the m-th row and n-th column of the FC value matrix.

Step 6: Post-processed Data Storage: Insert model parameters, potential difference matrix, and FC value matrix into the established pipe pitting corrosion database.

The database stores the model results for each calculated parameter, along with the previously processed potential difference matrix and FC value matrix. The database uses the calculated parameters from different models as a joint primary key.

The simulation model's calculation results, including pipe parameters, pitting morphology parameters, voltage values acquired by the electrode array, and the electric field fingerprint characteristic signal FC obtained through data preprocessing, are inserted into the established pipe pitting corrosion database table.

Step 7: Full-parameter simulation calculations: Traverse all set parameters of the models to complete the calculation and data storage of all set parameter models. Specifically: Based on the set calculation parameters, repeat steps 3 to 6 above to ensure that all set parameters of the models are traversed, and complete the simulation calculation, data post-processing, and storage of all set parameters.

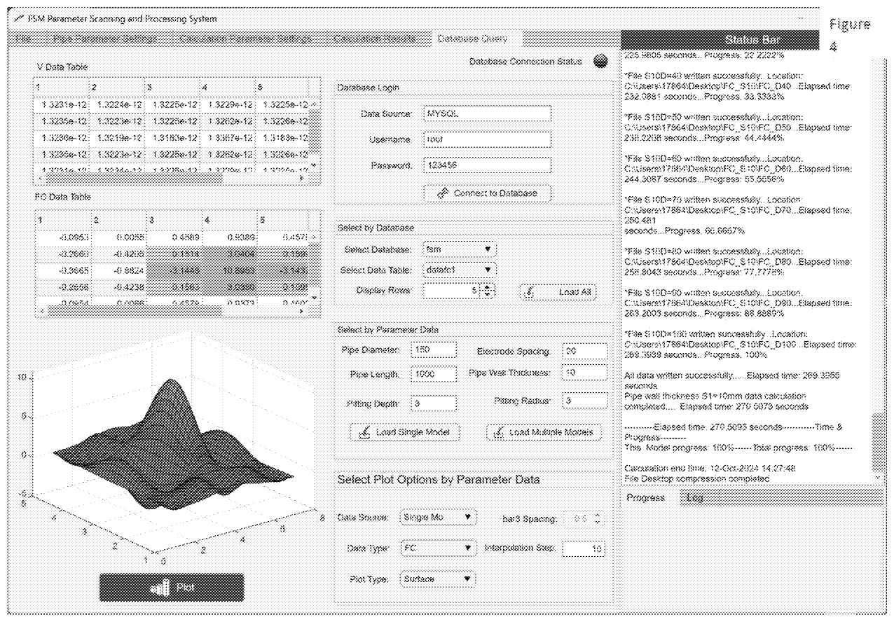

Step 8: Simulation Calculation Result Query: The system provides a database table query method, allowing users to select the models' calculation parameters and query the database for the simulation models' calculation results under those parameters. An example result of the present invention is shown in FIG. 4.

All parts of the present invention not described in detail herein can be referred to in the prior art or are well-known to those skilled in the art. This embodiment does not limit these aspects and will not describe them in detail here.

The embodiments of the present invention have been described above with reference to the accompanying drawings. However, the present invention is not limited to the specific embodiments described above. The specific embodiments described above are merely illustrative and not restrictive. Those skilled in the art, under the guidance of the present invention, can make many modifications without departing from the spirit and scope of the claims, and all such modifications are within the protection scope of the present invention.

1. A method for rapidly constructing field signature method databases, including following steps of:
S1—performing simulation requirement analysis, which includes calculating electric field distribution information of monitored components with pitting corrosion;
S2—setting simulation parameters and establishing simulation calculation models of the monitored components;
S3—performing simulation calculations: according to set simulation parameters, calculating electric field distribution information of models with pitting corrosion and models without pitting corrosion under all single parameters;
S4—extracting potential information from simulation models and constructing a potential matrix: according to preset electrode matrix parameters, constructing an electric field data extraction coordinate matrix and extracting potential information corresponding to coordinates;
S5—data post-processing: according to the potential matrix, constructing an initial potential difference matrix and a collected potential difference matrix respectively, and then calculating an FC value matrix, and
S6—data storage: inserting the simulation parameters, potential difference matrices, and FC value matrix as mentioned above into an existing pitting corrosion database, wherein
the step S3 includes:
calculation of models without pitting corrosion: selecting a single parameter from the simulation parameters of the monitored components as a parameter used for calculation, and calculating electric field distribution information of monitored component models without pitting corrosion under the single parameter; and
calculation of models with pitting corrosion: using the parameter in the calculation of models without pitting corrosion, and calculating electric field distribution information of monitored component models with pitting corrosion under the parameter.

2. The method for rapidly constructing field signature method databases according to claim 1 further including: traverse the steps S4-S6 to ensure that data for all parameters is stored in the pitting corrosion database.

3. The method for rapidly constructing field signature method databases according to claim 1 further including: using the simulation parameters and querying calculation results under the simulation parameters in the pitting corrosion database.

4. The method for rapidly constructing field signature method databases according to claim 1, wherein the step S1 includes confirming to-be-monitored object information, simulation calculation objectives, requirements, and corrosion defect information included for filed signature monitoring, and calculating electric field distribution information of monitored components with pitting corrosion based on the to-be-monitored object information, the simulation calculation objectives, the requirements, and the corrosion defect information included.

5. The method for rapidly constructing field signature method databases according to claim 1, wherein the step S2 includes following specific steps of:
S21—system construction: determining a programming language, multiphysics simulation software, and a database;
S22—setting model parameters of the monitored components, which include dimensions and material of the monitored components;
S23—setting pitting corrosion parameters: setting morphology parameters of the monitored components when pitting corrosion occurs, including pitting coordinate information and morphology parameter information; and
S24—setting physical field parameters: adding physical field parameters to the simulation models, applying direct current to both ends of the monitored components, and establishing simulation calculation models of the monitored components.

6. The method for rapidly constructing field signature method databases according to claim 6, wherein the morphology parameter information in the step S23 includes pitting radius and pitting depth.

7. The method for rapidly constructing field signature method databases according to claim 1, wherein the step S4 includes following specific steps of:
S41—constructing an electrode matrix: setting electrode matrix parameters of monitored component models, obtaining electrode coordinate information under different electrode matrix arrangements, and forming the electrode matrix; and
S42—constructing a potential matrix: according to the electrode coordinate information obtained, extracting potential information of sampling points contained in the electrode matrix, and obtaining the potential matrix.

8. The method for rapidly constructing field signature method database according to claim 1, wherein the step S5 includes:
according to the potential matrix, calculating potential differences between any two adjacent electrodes under both non-corroded and pitted corrosion conditions of the monitored components, obtaining an initial potential difference matrix and a collected potential difference matrix containing all electrode sites; and
according to the collected potential difference matrix and the initial potential difference matrix, calculating an FC value matrix, wherein
an FC value is a ratio of voltage values under the non-corroded and pitted corrosion conditions.

9. A device for rapidly constructing field signature method databases, including a memory, a processor, and a computer program stored in the memory and executable on the processor, wherein the processor executes the computer program to implement the steps of the method for rapidly constructing field signature method databases according to claim 1.
